(19) United States
(12) Patent Application Publication
(10) Pub. No.: US 2015/0004750 A1
(43) Pub. Date: Jan. 1, 2015

(54) Methods of Forming Conductive Materials on Contact Pads

(71) Applicant: STATS ChipPAC, Ltd., Singapore (SG)

(72) Inventors: HeeJo Chi, Kyoungki-do (KR); HanGil Shin, Seoul (KR); NamJu Cho, Gyeonggi-do (KR); KyungMoon Kim, Gyeonggi-do (KR)

(21) Appl. No.: 13/929,767

(22) Filed: Jun. 27, 2013

(51) Int. Cl. H01L 23/00; H01L 25/00

(52) U.S. Cl. CPC H01L 24/82; H01L 25/50
USPC 438/108; 438/125

(57) ABSTRACT

Methods of forming conductive materials on contact pads for semiconductor devices and packages. Substrate is provided with contact pads formed thereon. Conductive material is formed over the contact pads by a depositing process followed by a heating process to alter the chemical properties of the conductive material. Optionally, a dispersing process may be incorporated. An interconnect structure can be mounted over the conductive material where the interconnect structure is attached to the conductive material without any active treatment to the conductive material after formation.

### TECHNICAL FIELD

The present disclosure relates in general to semiconductor devices, more particularly, to methods of forming conductive materials on contact pads for semiconductor devices and packages.

### BACKGROUND

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly can refer to both a single semiconductor device and multiple semiconductor devices.

### SUMMARY

Methods of forming conductive materials on contact pads for semiconductor devices and packages. In one embodiment, a method of forming conductive materials on contact pads for semiconductor devices and packages includes: (a) providing a substrate having an upper surface and a lower surface opposite the upper surface, (b) forming a contact pad over the upper surface of the substrate, and (c) forming a conductive material over the contact pad. In one embodiment, the forming step (c) includes the following sub-steps: (i) depositing the conductive material having a first state and (ii) heating the conductive material from the first state to a second state, where the second state different than the first state. In another embodiment, the forming step (c) includes the following sub-steps: (i) depositing the conductive material, (ii) dispersing the conductive material from an initial area to a final area, where the final area is greater than the initial area, and (iii) heating the conductive material. Next, the method includes: (d) mounting an interconnect structure over the conductive material where the interconnect structure is attached to the conductive material without any active treatment to the conductive material after the forming step (c).

In some embodiments, the method further includes: (e) mounting a semiconductor package over the interconnect structure, where the semiconductor package includes an integrated circuit device. In other embodiments, the method further includes: (f) forming a plurality of external interconnects on the lower surface of the substrate, where the external interconnects are in communication with the integrated circuit device.

In one embodiment, the depositing step (i) of the forming step (c) includes depositing the conductive material including at least one of silver (Ag), platinum (Pt), gold (Au), copper (Cu), carbon nanotube (CNT), graphene, organic metal, and mixtures thereof. In another embodiment, the forming step (c) includes forming the conductive material over the contact pad to prevent oxidation of the contact pad. In yet another embodiment, the method further includes treating the contact pads with hydrophilic plasma prior to the forming step (c).

In one embodiment, a method of forming conductive materials on contact pads for semiconductor devices and packages includes: (a) providing a substrate having an upper surface and a lower surface opposite the upper surface and (b) forming first and second sets of contact pads over the upper surface of the substrate. In this embodiment, the first set of contact pads is disposed about a central region of the substrate and the second set of contact pads is disposed about a peripheral region of the substrate. Next, the method includes: (c) mounting an integrated circuit device over the first set of contact pads followed by (d) forming a conductive material over the second set of contact pads.

In one embodiment, the forming step (c) includes the following sub-steps: (i) depositing the conductive material having a first state and (ii) heating the conductive material from the first state to a second state, where the second state different than the first state. In another embodiment, the forming step (c) includes the following sub-steps: (i) depositing the conductive material, (ii) dispersing the conductive material from an initial area to a final area, where the final area is greater than the initial area, and (iii) heating the conductive material.

Next, the method includes: (e) mounting an interconnect structure over the conductive material, where the interconnect structure is attached to the conductive material without any active treatment to the conductive material after the forming step (d). In some embodiments, the method further includes: (f) mounting a semiconductor package over the interconnect structure, where the semiconductor package is in communication with the integrated circuit device. In other embodiments, the method further includes: (g) forming a plurality of external interconnects on the lower surface of the substrate, where the external interconnects are in communication with at least one of the semiconductor package and the integrated circuit device.

In one embodiment, the mounting step (c) includes mounting the integrated circuit device over the first set of contact pads, where the integrated circuit device is a flip chip device. In another embodiment, the depositing step (i) of the forming step (d) includes depositing the conductive material including at least one of silver (Ag), platinum (Pt), gold (Au), copper (Cu), carbon nanotube (CNT), graphene, organic metal, and mixtures thereof. In yet another embodiment, the forming step (d) includes forming the conductive layer over the second set of contact pads to prevent oxidation of the second set of contact pads. In some instances, the method further includes treating the second set of contact pads with hydrophilic plasma prior to the forming step (d).

In one embodiment, a method of forming conductive materials on contact pads for semiconductor devices and packages includes: (a) providing a substrate having an upper surface and a lower surface opposite the upper surface and (b) forming first, second and third sets of contact pads on the substrate. In this embodiment, the first set of contact pads is formed on the lower surface, the second set of contact pads is formed on the upper surface, and the third set of contact pads is formed on the upper surface, where the third set of contact pads is adjacent the second set of contact pads. Next, the method includes: (c) mounting an integrated circuit device over the third set of contact pads and (d) forming a first conductive material over the first set of contact pads.

In one embodiment, the forming step (d) includes the following sub-steps: (i) depositing the first conductive material having a first state and (ii) heating the first conductive material from the first state to a second state, where the second state is different than the first state. In another embodiment, the forming step (d) includes the following sub-steps: (i) depositing the first conductive material, (ii) dispersing the first conductive material from first initial area to first final area, where the first final area is greater than the first initial area, and (iii) heating the first conductive material.

Next, the method includes: (e) forming a second conductive material over the second set of contact pads having the following sub-steps: (i) depositing the second conductive material having a third state and (ii) heating the second conductive material from the third state to a fourth state, where the fourth state is different than the third state. In another embodiment, the forming step (e) includes the following sub-steps: (i) depositing the second conductive material, (ii) dispersing the second conductive material from second initial area to second final area, where the second final area is greater than the second initial area, and (iii) heating the second conductive material.

In one embodiment, the method includes: (f) forming a plurality of external interconnects over the first conductive material, where the external interconnects are coupled to the first conductive material without any active treatment to the first conductive material after the forming step (d). In another embodiment, the method includes: (g) mounting an interconnect structure over the second conductive material, where the interconnect structure is attached to the second conductive material without any active treatment to the second conductive material after the forming step (e). In one embodiment, the forming step (b) includes forming the second set of contact pads about a peripheral region of the upper surface of the substrate and forming the third set of contact pads about a central region of the upper surface of the substrate.

In some embodiments, the method further includes: forming a third conductive material over the third set of contact pads prior to the mounting step (c), where the forming step includes the following sub-steps: (i) depositing the third conductive material having a fifth state and (ii) heating the third conductive material from the fifth state to a sixth state, where the sixth state is different than the fifth state. In other embodiments, the forming step includes the following sub-steps: (i) depositing the third conductive material, (ii) dispersing the third conductive material from third initial area to third final area, where the third final area is greater than the third initial area, and (iii) heating the third conductive material.

In one embodiment, forming of the third conductive material prior to the mounting step (c) and the forming step (e) can be carried out concurrently. In another embodiment, the mounting step (c) includes mounting the integrated circuit device over the third set of contact pads, where the integrated circuit device is a flip chip device. In some embodiments, the method further includes: (h) mounting a semiconductor package over the interconnect structure, where the semiconductor package is in communication with the integrated circuit device. In other embodiments, the forming step (f) includes forming the plurality of external interconnects over the first conductive material, where the plurality of external interconnects are in communication with at least one of the semiconductor package and the integrated circuit device.

Other variations, embodiments and features of the present disclosure will become evident from the following detailed description, drawings and claims.

### BRIEF DESCRIPTION OF THE DRAWINGS

FIG. 1 illustrates a printed circuit board (PCB) with different types of packages mounted to its surface.

FIGS. 2a-2c illustrate further detail of the representative semiconductor packages mounted to the PCB.

FIGS. 3a-3b illustrate details of a representative semiconductor substrate.

FIG. 4 is a cross-sectional view of a semiconductor package.

FIG. 5 is a close-up view of a portion of FIG. 4 illustrating a conductive material formed on a contact pad.

FIGS. 6A-6F are process flows of methods of forming conductive materials on contact pads.

FIGS. 7A-7E are process flows of methods of forming conductive materials on contact pads.

FIG. 8 is a cross-sectional view of a semiconductor package having a conductive material formed on a contact pad.

FIG. 9 is a flow diagram of methods of forming conductive materials on contact pads.

### DETAILED DESCRIPTION OF THE DISCLOSURE

It will be appreciated by those of ordinary skill in the art that the embodiments disclosed herein can be embodied in other specific forms without departing from the spirit or essential character thereof. The presently disclosed embodiments are therefore considered in all respects to be illustrative and not restrictive.

The present disclosure is described in one or more embodiments in the following description with reference to the figures, in which like numerals represent the same or similar elements. While the disclosure is described in terms of the best mode for achieving the disclosure's objectives, it will be appreciated by those skilled in the art that it is intended to cover alternatives, modifications, and equivalents as may be included within the spirit and scope of the disclosure as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, i.e., the negative photoresist, is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Patterning is the basic operation by which portions of the top layers on the semiconductor wafer surface are removed. Portions of the semiconductor wafer can be removed using photolithography, photomasking, masking, oxide or metal removal, photography and stenciling, and microlithography. Photolithography includes forming a pattern in reticles or a photomask and transferring the pattern into the surface layers of the semiconductor wafer. Photolithography forms the horizontal dimensions of active and passive components on the surface of the semiconductor wafer in a two-step process. First, the pattern on the reticle or masks is transferred into a layer of photoresist. Photoresist is a light-sensitive material that undergoes changes in structure and properties when exposed to light. The process of changing the structure and properties of the photoresist occurs as either negative-acting photoresist or positive-acting photoresist. Second, the photoresist layer is transferred into the wafer surface. The transfer occurs when etching removes the portion of the top layers of semiconductor wafer not covered by the photoresist. The chemistry of photoresists is such that the photoresist remains substantially intact and resists removal by chemical etching solutions while the portion of the top layers of the semiconductor wafer not covered by the photoresist is removed. The process of forming, exposing, and removing the photoresist, as well as the process of removing a portion of the semiconductor wafer can be modified according to the particular resist used and the desired results.

In negative-acting photoresists, photoresist is exposed to light and is changed from a soluble condition to an insoluble condition in a process known as polymerization. In polymerization, unpolymerized material is exposed to a light or energy source and polymers form a cross-linked material that is etch-resistant. In most negative resists, the polymers are polyisopremes. Removing the soluble portions (i.e. the portions not exposed to light) with chemical solvents or developers leaves a hole in the resist layer that corresponds to the opaque pattern on the reticle. A mask whose pattern exists in the opaque regions is called a clear-field mask.

In positive-acting photoresists, photoresist is exposed to light and is changed from relatively nonsoluble condition to much more soluble condition in a process known as photosolubilization. In photosolubilization, the relatively insoluble resist is exposed to the proper light energy and is converted to a more soluble state. The photosolubilized part of the resist can be removed by a solvent in the development process. The basic positive photoresist polymer is the phenol-formaldehyde polymer, also called the phenol-formaldehyde novolak resin. Removing the soluble portions (i.e. the portions exposed to light) with chemical solvents or developers leaves a hole in the resist layer that corresponds to the transparent pattern on the reticle. A mask whose pattern exists in the transparent regions is called a dark-field mask.

After removal of the top portion of the semiconductor wafer not covered by the photoresist, the remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual semiconductor die and then packaging the semiconductor die for structural support and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

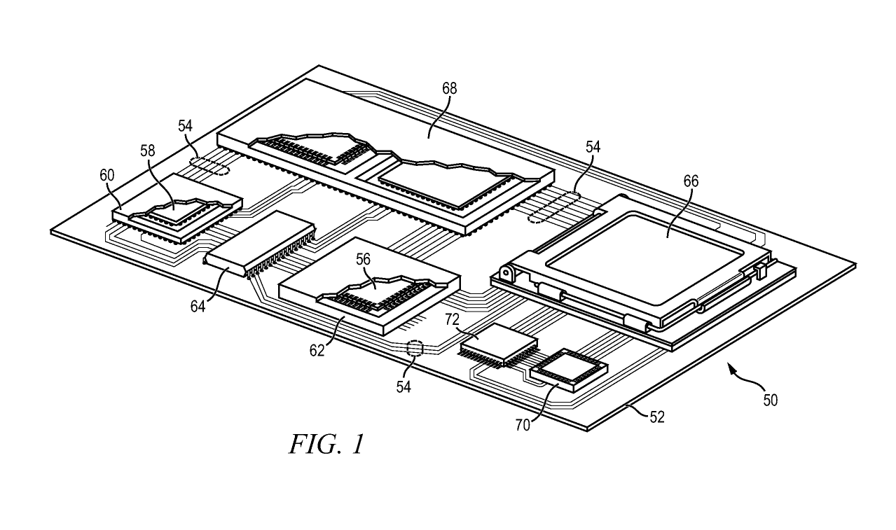

FIG. 1 illustrates electronic device 50 having a chip carrier substrate or printed circuit board (PCB) 52 with a plurality of semiconductor packages mounted on its surface. Electronic device 50 can have one type of semiconductor package, or multiple types of semiconductor packages, depending on the application. The different types of semiconductor packages are shown in FIG. 1 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for these products to be accepted by the market. The distance between semiconductor devices must be decreased to achieve higher density.

In FIG. 1, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

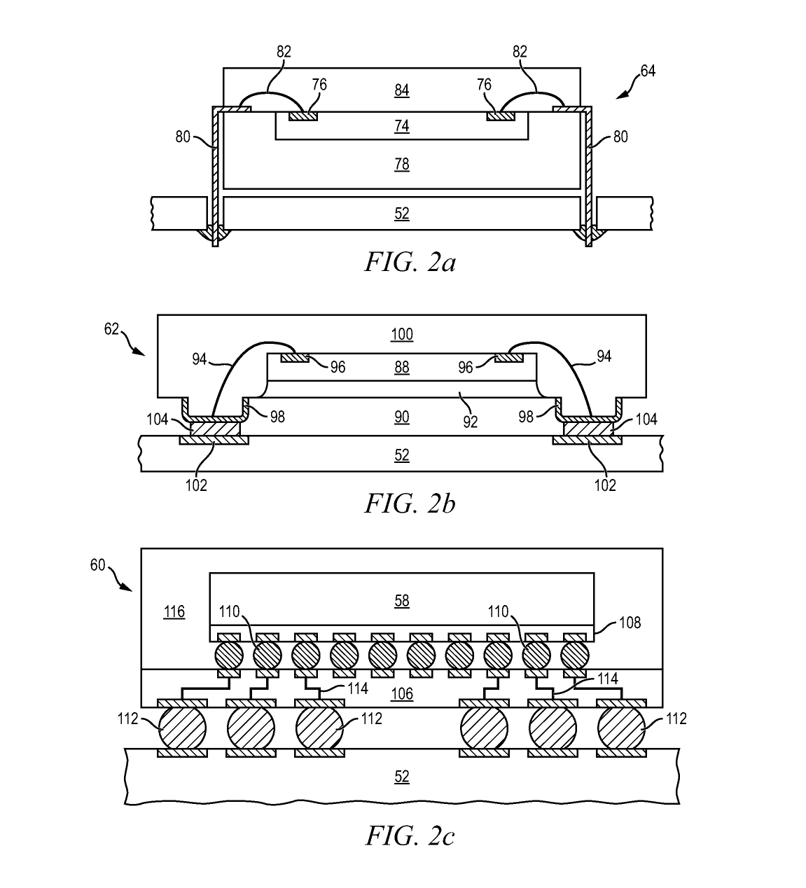

FIGS. 2a-2c show exemplary semiconductor packages. FIG. 2a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit can include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and bond wires 82 provide electrical interconnect between semiconductor die 74 and PCB 52. Encapsulant 84 is deposited over the package for environmental protection by preventing moisture and particles from entering the package and contaminating semiconductor die 74 or bond wires 82.

FIG. 2b illustrates further detail of BCC 62 mounted on PCB 52. Semiconductor die 88 is mounted over carrier 90 using an underfill or epoxy-resin adhesive material 92. Bond wires 94 provide first level packaging interconnect between contact pads 96 and 98. Molding compound or encapsulant 100 is deposited over semiconductor die 88 and bond wires 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 2c, semiconductor die 58 is mounted face down to intermediate carrier 106 with a flipchip style first level packaging. Active region 108 of semiconductor die 58 contains analog or digital circuits implemented as active devices, passive devices, conductive layers, and dielectric layers formed according to the electrical design of the die. For example, the circuit can include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flipchip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flipchip style first level packaging without intermediate carrier 106.

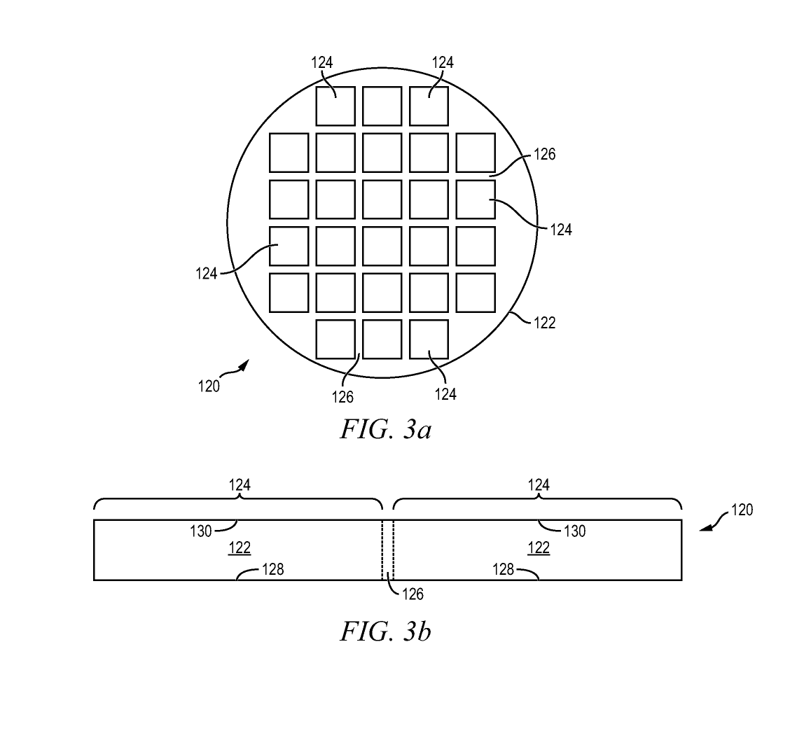

FIG. 3a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by a non-active, inter-die wafer area or saw street 126 as described above. Saw street 126 provides cutting areas to singulate semiconductor wafer 120 into individual semiconductor die 124.

FIG. 3b shows a cross-sectional view of a portion of semiconductor wafer 120. Each semiconductor die 124 has a back surface 128 and active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing.

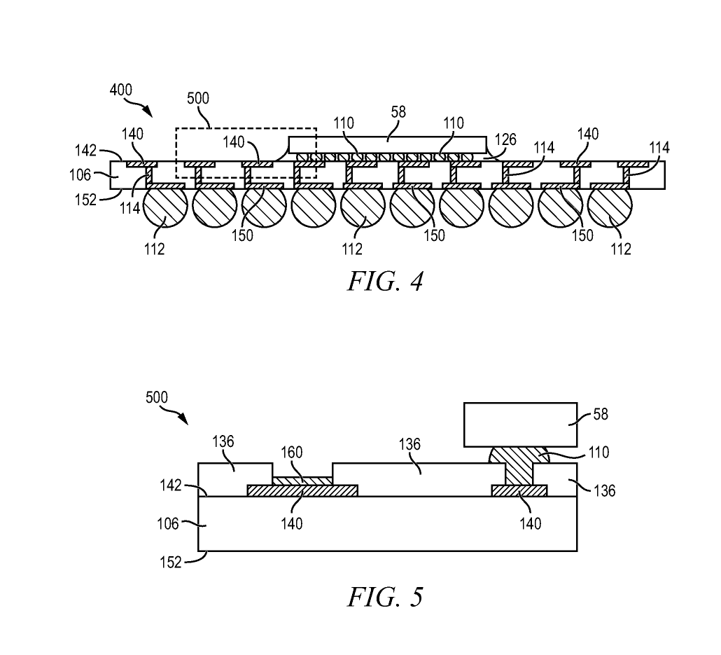

FIG. 4 is a cross-sectional view of a semiconductor package 400 according to one embodiment of the present disclosure. As shown, the package 400 includes a substrate 106 having an integrated circuit device 58 formed thereon. The substrate 106 can be a semiconductor wafer or a chip carrier similar to those described above. The integrated circuit device 58 can be attached to the substrate 106 via a plurality of bumps 110. The bumps 110 may be underfilled or encapsulated with a molding compound 126 such as an epoxy material, along with portions of the lower surface of the integrated circuit device 58 facing the substrate 106. In some instances, the molding compound 126 may be optional leaving the bumps 110 as well as the lower surface of the integrated circuit device 58 substantially open or exposed to the elements.

The substrate 106 can include an upper surface 142 and a lower surface 152, the upper surface 142 having top contact pads 140 formed thereon and the lower surface 152 having bottom contact pads 150 formed thereon. The contact pads 140, 150 can be formed with known deposition processes including the likes electroplating, physical vapor deposition or chemical vapor deposition, among other suitable deposition techniques. The contact pads 140, 150 can include a variety of metals including copper, gold, platinum, among others. In some instances, the contact pads 140, 150 can include an organic solderability preservative (OSP) on top of the metal contact for purposes of protecting the metal contact underneath during a soldering process. In general, the OSP material cannot be preserved after various backend processes (e.g., chip attach, die attach, baking, plasma, reflow, wire bonding, molding) due to thermal treatments thus resulting in oxidation of the metal contacts underneath. As such, optionally, a solder on pad (SOP) may be formed over the OSP. In another embodiment, a gold layer or nickel gold (Ni/Au) layer may be formed on the top contact pad 140 by electroplating to prevent oxidation of the top contact pad 140 until additional packaging processes can be carried out. For example, assuming the top contact pad 140 is copper, the nickel gold layer may be deposited thereon to prevent oxidation of the copper during subsequent semiconductor processes. In another example, an electroless-nickel electroless-palladium immersion gold (ENEPIG) material may be used in place of the nickel gold to prevent oxidation.

The top contact pad 140 and the bottom contact pad 150 can be in communication via signal lines 114. The signal lines 114 may be similar to those described above including for example, through-silicon via (TSV) or molded laser via, among other suitable interconnects. In some instances, the substrate 106 may be an interposer with pre-formed electrical connections between the upper and lower surfaces 142, 152. Solder bumps 112 may subsequently be formed on the bottom contact pad 150 for signal routing purposes, the bumps 112 being in communication with the integrated circuit device 58.

FIG. 5 is a close-up view 500 of a portion of FIG. 4 illustrating formation of a conductive material on a contact pad according to one embodiment of the present disclosure. Similar to that described above, the close-up view 500 includes a substrate 106 having an integrated circuit device 58 formed thereon. A bump 110 can be used to connect the integrated circuit device 58 to the substrate 106 via the top contact pad 140. In this instance, the molding compound 126 has been eliminated for ease of illustration, but it will be appreciated by one skilled in the art that the molding compound 126 may be formed around the bump 110 underneath the integrated circuit device 58 similar to that described above.

A dielectric material or solder resist 136 may be formed around the top contact pads 140. The solder resist 136 may be formed by deposition and photolithography, among other suitable techniques. Likewise, a dielectric material can be formed by deposition, lithography and etching to arrive at the desired pattern. As illustrated, the opening formed by the solder resist 136 may be slightly less than the width of the top contact pad 140 although that need not be the case. The narrowed opening may allow a conductive layer or material 160 to be formed on the top contact pad 140 according to one embodiment of the present disclosure.

In some embodiments, the conductive material 160 can be formed by a direct writing process including the likes of screen printing or electro-hydro dynamic (EHD) dispensing. Screen printing involves the use of a paste material, screen mesh, an emulsion material and application of force via an applicator with the substrate held by a nest. In the alternative, EHD dispensing involves the use of an electric field to dispense droplets from a nozzle. In other embodiments, formation of the conductive material 160 can include the likes of inkjet printing, which can be continuous or on demand, and can be carried out in vertical or horizontal fashion. The use of inkjet printing to form the conductive material 160 on contact pads 140 may provide visible and conductive metal lines that are halogen free. The ink material that is involved may be of an organic metal or a silver complex.

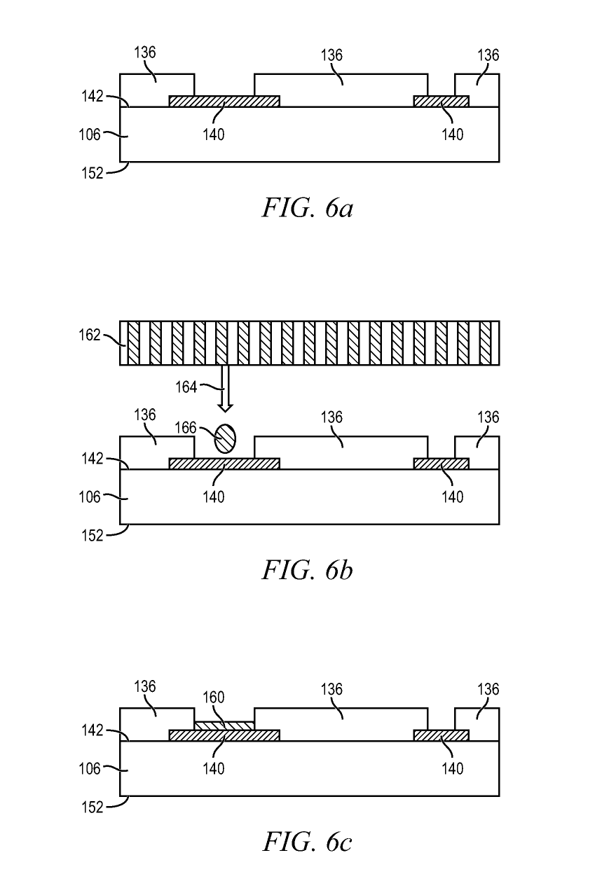

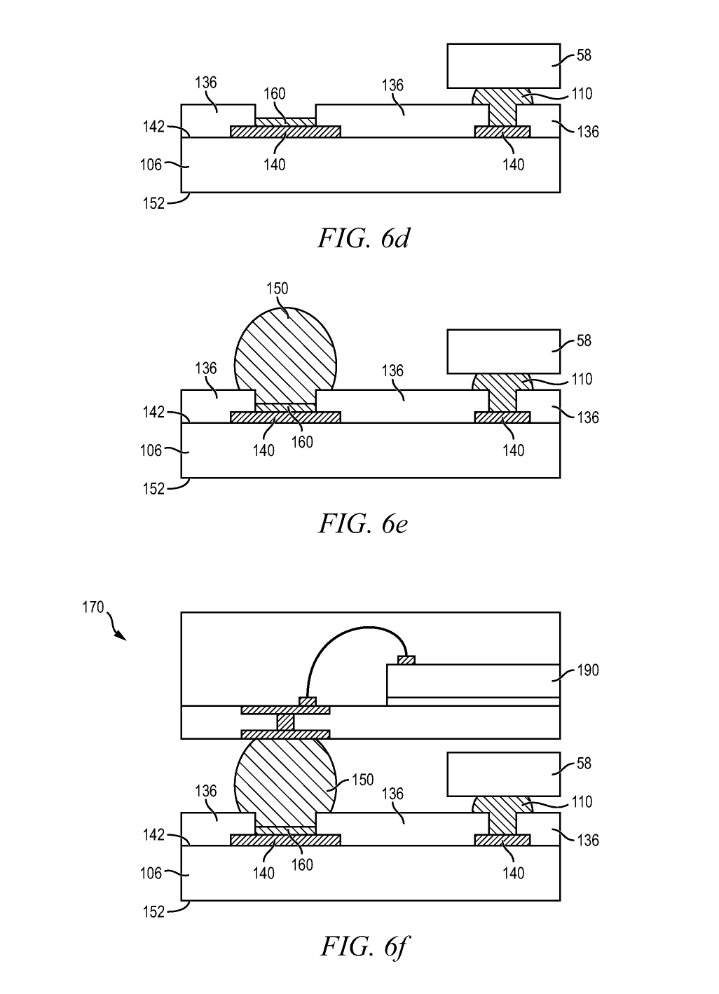

FIGS. 6A-6F are process flows of a method of forming conductive materials on contact pads according to one embodiment of the present disclosure. FIG. 6A starts with a substrate 106 being provided, where the substrate 106 includes an upper surface 142 and a lower surface 152, the lower surface 152 being opposite the upper surface 142. A contact pad 140 similar to that described above can be formed over the upper surface 142 of the substrate 106. A solder resist 136 may subsequently be formed over the substrate 106 and on the contact pad 140. The solder resist 136 may help to facilitate formation of the conductive material 160.

FIG. 6B shows the beginning steps of forming a conductive material 160 over the contact pad 140 using an inkjet printing process. An inkjet head 162 may be provided over the desired area of interest. The inkjet head 162 can deliver a resolution of 1,200 dots per inch (DPI) although other inkjet heads 162 with other resolution may be utilized. Upon passing over the desired area, a nozzle 164 from the inkjet head 162 may cause an inkjet droplet 166 to be deposited onto the contact pad 140. The inkjet droplet 166, containing the ink material, will subsequently be formed into the desired conductive material layer 160. In this example, the deposition can be accomplished via gravity. In other instances, the deposition can be carried out via other suitable mechanical and/or electrical assistance including the likes of an electric field, for example.

The number of nozzles 164 on the inkjet head 162 can vary. For example, there can be a total of 2,048 nozzles 164 providing coverage width of about 43 millimeters. The nozzles 164 and the head 162 may have a writing speed of about 200 millimeters per second. The number of droplets 166 can be varied depending on the desired thickness and/or width of the conductive material 160 to be achieved. For example, the number of droplets 166 can vary between about 1 droplet to about 10 droplets, or greater than 10 droplets 166. The inkjet droplet 166 may have a diameter of anywhere from about 3 microns to about 12 microns depending on the viscosity and the volume of the ink being consumed. Meanwhile, the thickness of the conductive material 160 formed may be about 3 microns thick, or thinner than 3 microns, or thicker than 3 microns. In this instance, the amount of ink can be about 1 picoliter. Because of the plurality of nozzles 164 and the speed at which the head 162 can process a substrate, inkjet printing throughput can be on the matter of seconds per strip of devices.

In one embodiment, the inkjet droplet 166 may be a conductive material 160 in ink or liquid form. The types of conductive material 160 that can be in liquid or ink form include silver (Ag), platinum (Pt), gold (Au), copper (Cu), carbon nanotube (CNT), graphene, organic metal, or mixtures thereof. In another embodiment, the inkjet droplet 166 that ultimately forms the conductive layer 160 may be a conductive polymeric material with metallic properties.

In another embodiment, instead of using inkjet printing and inkjet droplet 166, conductive material 160 may be deposited in paste form and that deposition can be made by screen printing or EHD dispensing. The paste may have material properties similar to the inkjet droplet 166 disclosed above including without limitation silver (Ag) paste, platinum (Pt) paste, gold (Au) paste or copper (Cu) paste, to name a few.

In one embodiment, prior to the deposition of the inkjet droplet 166 as shown in FIG. 6B, the contact pads 140 may be treated with hydrophilic plasma. Treating the contact pads 140 with hydrophilic plasma may raise the surface energy of the contact pads 140 leading to increased dispersion of the conductive ink. This will become more apparent in subsequent figures and discussion.

FIG. 6C shows the inkjet droplet 166, now sitting on the contact pad 140, being allowed to disperse and spread out. Because of the low viscosity (<100 centipoise), the inkjet droplet 166 is able to spread out to cover the desired surface area. For example, the inkjet droplet 166 may have an initial area upon deposition as best illustrated in FIG. 6B. In this example, the initial area may be in the range of from about 10-15 microns (e.g., diameter of the droplet 166). In time, the inkjet droplet 166 may disperse or be allowed to disperse thereby arriving at a final area. In one embodiment, the final area is greater than the initial area. The final area may be substantially similar to the opening width as narrowed by the solder resist 136 over the contact pad 140. For example, the contact pad 140 may have a width of about 200 microns while the width of the opening narrowed by the solder resist 136 may be about 150 microns, the 150 microns being the final area or width that the inkjet droplet 166 may disperse. In other words, the initial area may be about 15 microns while the final area may be about 150 microns. The dispersion of about 10-fold can be accomplished because of the low viscosity of the inkjet droplet 166. The dispersion may be further enhanced if the top of the contact pad 140 had been subjected to the hydrophilic plasma process as discussed above, which helps to raise the surface energy and enhance the dispersion process.

In another embodiment, if the screen printing or EHD dispensing is utilized, no dispersion step would be necessary as the desired profile may already be formed after the deposition step.

After deposition and optional dispersion of the conductive material 160, a heating process may be carried out to further sinter the material. In one embodiment, the heating process may include oven or ultra-violet curing or both. The heating process may also include a reflow process for purposes of sintering the conductive particles that are in the conductive ink or paste material 160. Once heated or cured, the conductive material 160, formed over the contact pad 140, may prevent oxidation of the contact pad 140 underneath, in similar manner as those of Ni/Au and ENEPIG.

FIG. 6D shows that the integrated circuit device 58 can be mounted to the substrate 106 via a plurality of solder bumps 110. In this instance, the solder bumps 110 are directly mounted to the contact pad 140 without any conductive material 160 in between, although it is understood that the solder bumps 110 can be mounted to the contact pads 140 with the addition of a conductive material 160. In this instance, the integrated circuit device 58 can be a flip chip device. Although the mounting of the integrated circuit device 58 is shown after formation of the conductive material 160, it is possible that the integrated circuit device 58 can be formed prior to formation of the conductive material 160. In other words, the integrated circuit device 58 can be mounted to the substrate 106 as far back as in FIG. 6A.

FIG. 6E shows an interconnect structure 150 being mounted over the conductive material 160, where the interconnect structure 150 can be attached to the conductive material 160 without any active treatment to the conductive material 160 post formation. Active treatment can be defined as subjecting a surface of a material to a process that would cause chemical changes or alterations on the surface of the material. For example, depositing flux followed by reflow of the flux and rinsing would be considered an active treatment process because flux cleaning would cause removal of an oxide from the surface. Heating of the material to a point that causes material composition changes or alterations may constitute active treatment. In contrast, coating a photoresist on a surface followed by lithography and removal of the photoresist without substantially altering the chemical properties of the surface would not constitute active treatment because no chemical changes took place. Likewise, rinsing with distilled water may also be considered as an inactive or not an active treatment process.

In this instance, as discussed above, because the conductive material 160 can help to protect the contact pad 140 underneath during a soldering step by preventing oxidation of the contact pad 140, no addition active treatment (e.g., flux cleaning, reflow and rinsing) are necessary to the conductive material 160 for the subsequent mounting of the interconnect structure 150 (e.g., solder bump).

FIG. 6F shows a semiconductor package 170 being mounted over the interconnect structure 150, the semiconductor package 170 having an integrated circuit device 190 similar to those described above. In this instance, the integrated circuit device 190 can be wire bonded to the substrate of the package 170. The integrated circuit device 190 can be in electrical communication with the interconnect structure 150, as well as the integrated circuit device 58 through various signal paths and routes embedded within the substrate 106, including those on the upper surface 142 and the lower surface 152 (not shown).

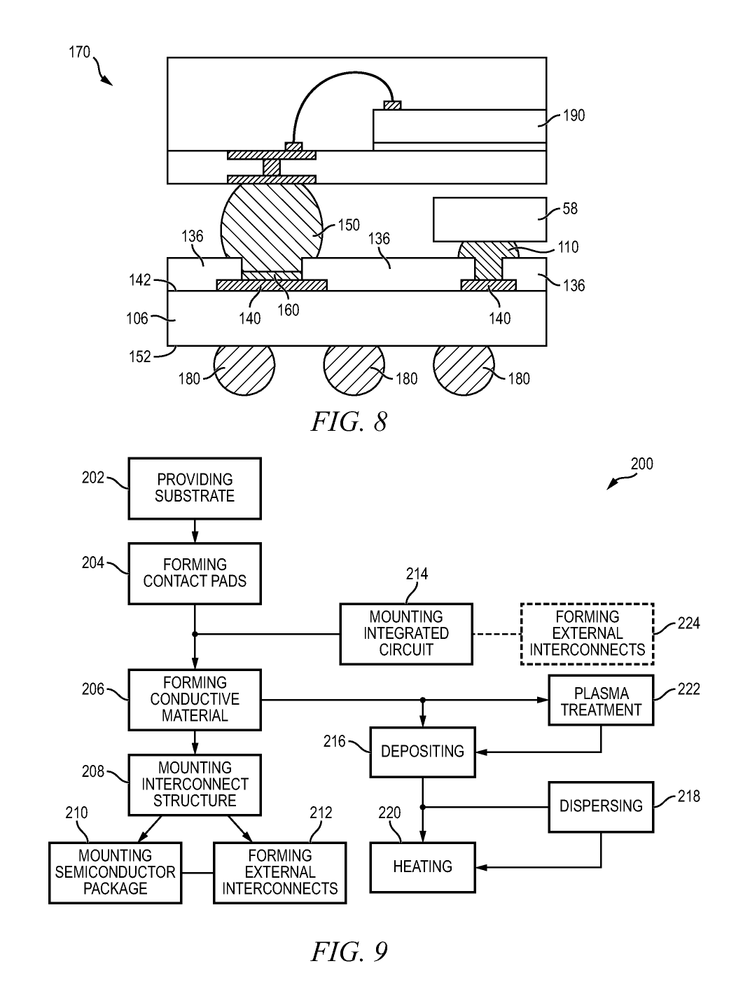

In one embodiment, a plurality of external interconnects 180 similar to the solder bumps 112 as shown in FIG. 4 can be formed on the lower surface 152 of the substrate 106 similar to those best illustrated in FIG. 8. Formation of the external interconnects 180 can allow electrical communication with the integrated circuit device 190 of the semiconductor package 170. In other words, electrical communication may be transmitted from the integrated circuit device 190 out of the semiconductor package 170, through the interconnect structure 150 and ultimately to the external interconnects 180. Alternatively, electrical communication may be transmitted from the integrated circuit device 58 directly to the external interconnects 180.

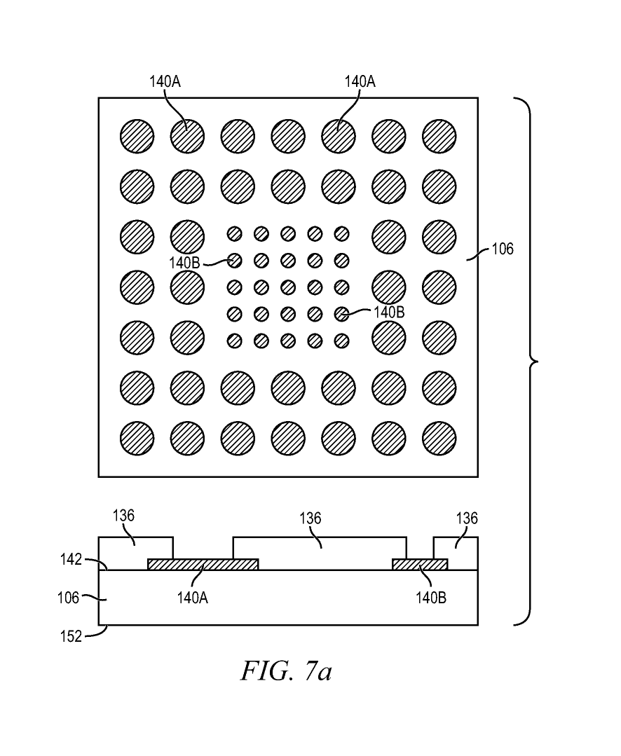

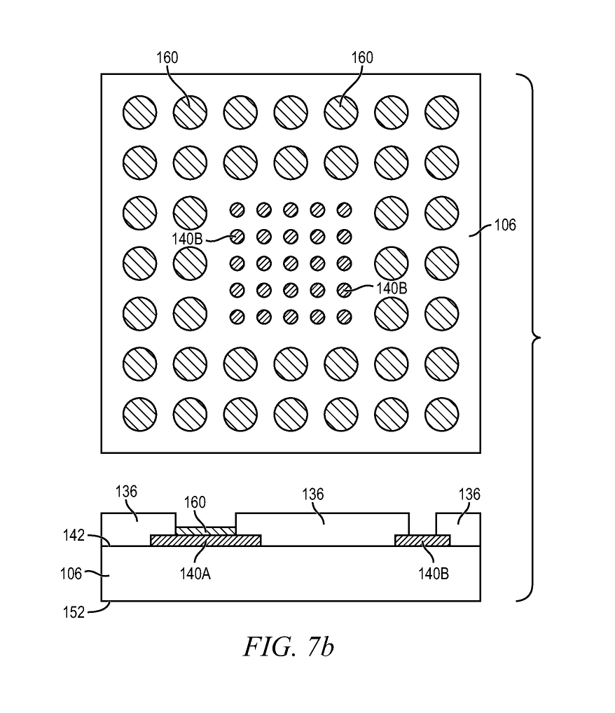

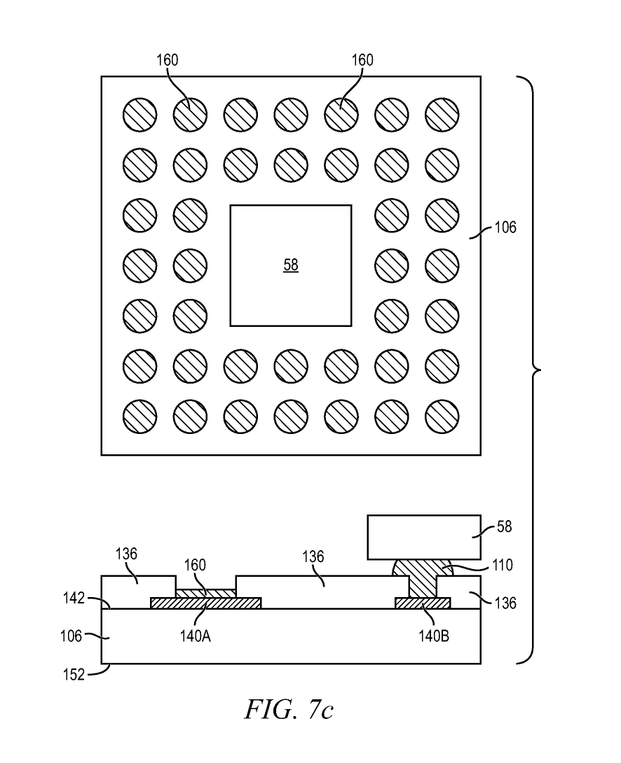

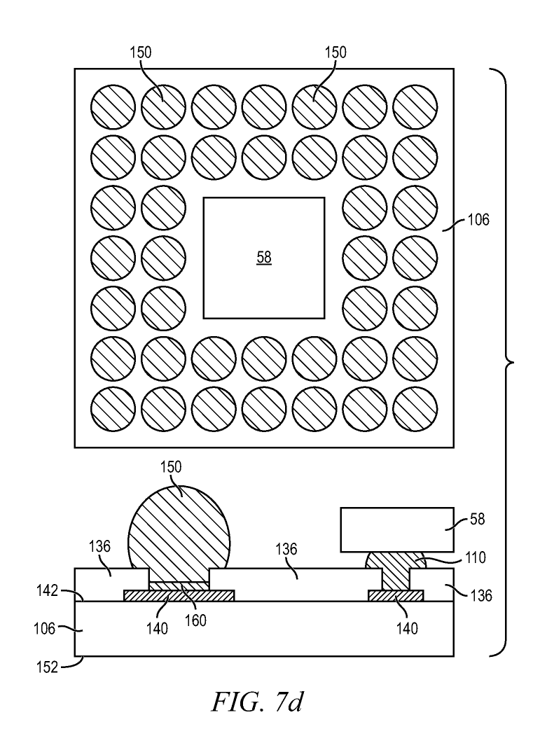

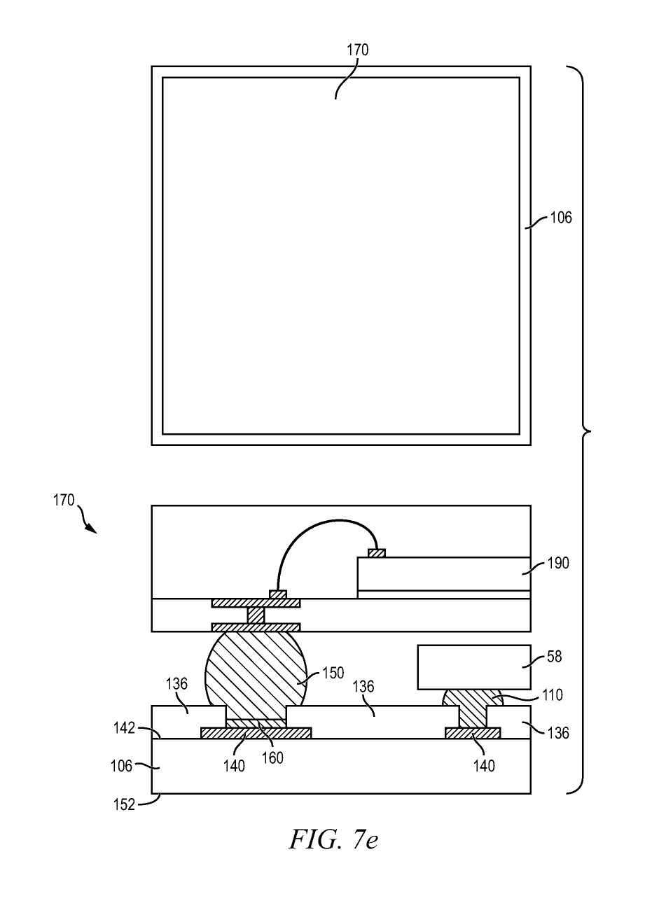

FIGS. 7A-7E are process flows of a method of forming conductive materials on contact pads according to one embodiment of the present disclosure. FIG. 7A includes top and cross-sectional views of a substrate 106 provided, where the substrate 106 includes an upper surface 142 and a lower surface 152, the lower surface 152 being opposite the upper surface 142. A first set of contact pads 140B can be formed about a central region of the substrate 106 while a second set of contact pads 140A can be formed about a peripheral region of the substrate 106. The contact pads 140A, 140B can be formed on the upper surface 142 of the substrate 106. Although described as two sets of contact pads 140A, 140B, it is understood that the two sets of contact pads 140A, 140B can be formed at the same time. Like above, a solder resist 136 may be formed over the substrate 106 and on the contact pad 140 to facilitate formation of the conductive material 160.

FIG. 7B shows the next step of the process flow where the conductive material 160 can be selectively formed on the second set of contact pads 140A but not on the first set of contact pads 140B. Formation of the conductive material 160 may be substantially similar to that described above in FIGS. 6A-6C and therefore will not be elaborated herein. In general, formation of the conductive material 160 over the second set of contact pads 140A includes depositing the conductive material 160, optionally allowing the conductive material 160 to disperse from an initial area to a final area, where the final area is greater than the initial area, and heating or curing the conductive material into a solid form. In the alternative, if screen printing or EHD dispensing is utilized, the conductive liquid or paste may be deposited having a first material state, where the first material state includes liquid, viscous or paste form. The conductive liquid or paste need not go through the dispersion or spreading process but instead can be heated from the first material state to a second material state, where the second material state is different from the first material state. The second material state may include solid, crystal or sintered form. In some embodiments, the first state may have an initial profile while the second state may have a final profile where the final profile is different from the initial profile. The difference in the profile may be a result of the heating or curing process which may drive out the fluid or viscous material in the liquid or paste causing the conductive material to undergo shrinkage into a more solid or sintered form.

The conductive ink, paste or liquid used in the formation of the conductive material 160 may include silver (Ag) complexes, platinum (Pt) complexes, gold (Au) complexes, copper (Cu) complexes, carbon nanotube (CNT), graphene, organic metal, or additives and mixtures thereof. The conductive ink, paste or liquid may also be an organic polymer with metallic properties. Similar to above, the second set of contact pads 140A can be treated with hydrophilic plasma prior to deposition of the conductive material 160 to enhance the dispersing process, as necessary.

FIG. 7C shows the mounting of an integrated circuit device 58 over the first set of contact pads 140B. The integrated circuit device 58 and the bumps 110 can be mounted over the first set of contact pads 140B similar to that described above. In this case, the integrated circuit device 58 can be a flip chip device. The top view shows the integrated circuit device 58 extending to cover the first set of contact pads 140B but leaving the second set of contact pads 140A substantially exposed. And although the cross-sectional view shows that the integrated circuit device 58 directly mounted to the contact pad 140B without a conductive material 160 in between, it is understood that a conductive material 160 can be formed over the contact pad 140B prior to formation of the bump 110 and the mounting of the integrated circuit device 58.

FIG. 7D shows a plurality of interconnect structures 150 being mounted over the conductive material 160, where the interconnect structures 150 are attached to the conductive material 160 without any active treatment to the conductive material 160 similar to that discussed above. Because the conductive material 160 over the second set of contact pads 140A can prevent oxidation of the second set of contact pads 140A, no subsequent active treatment of the conductive material 160 is necessary because there are no oxides to be removed from a surface of the conductive material 160.

FIG. 7E shows a semiconductor package 170 being mounted over the interconnect structures 150, where the semiconductor package 170 can be in communication with the integrated circuit device 58. From the top view one can see that the semiconductor package 170, once mounted, can substantially cover the entire substrate 106. It is understood that the interconnect structures 150 and the integrated circuit die 58 are underneath the semiconductor package 170 as can be appreciated from the top view. In some embodiments, the semiconductor package 170 may include an integrated circuit device 190 of its own. This integrated circuit device 190 may be similar or different from the integrated circuit device 58 mounted on the upper surface 142 of the substrate 106. In this instance, the coupling of the top semiconductor package 170 to the substrate 106 may result in the formation of a package-on-package (PoP) structure. By leaving the integrated circuit device 58 un-encapsulated or not underfilled, this PoP structure includes a bare die or exposed die (e.g., integrated circuit device 58).

FIG. 8 is a cross-sectional view of a semiconductor package having a conductive material formed on a contact pad. This package can be formed from that of FIG. 6F or FIG. 7E with the addition of a plurality of external interconnects 180 formed on the lower surface 152 of the substrate 106. In one embodiment, the external interconnects 180 may serve to provide electrical communication with the integrated circuit device 190 of the semiconductor package 170. In other words, electrical signals or communication may be transmitted from the integrated circuit device 190 out of the semiconductor package 170, through the interconnect structure 150 and ultimately to the external interconnects 180. In the alternative, electrical signals or communication may also be transmitted from the integrated circuit device 58 out through the external interconnects 180. In some embodiments, the external interconnects 180 may be in communication with the semiconductor package 170 or the integrated circuit device 58 or both. In other embodiments, the external interconnects 180 may be in communication with the integrated circuit device 190, or the semiconductor package 170, or the integrated circuit device 58, or all three.

Although the conductive material 160 has been described to be formed on the upper surface 142 of the substrate 106, namely, on the interior and exterior contact pads 140B, 140A, it will be understood and appreciated by one skilled in the art that the conductive material 160 can also be formed on the lower surface 152 of the substrate 106. Specifically, the conductive material 160 can be formed on the bottom contact pads 150 in a similar manner as that formed on the top contact pad 140. In other words, conductive material 160 may be formed on the set of bottom contact pads 150 similar to that formed on the top contact pads 140 with the same depositing, optional dispersing, and heating steps as described above. The plurality of external interconnects 180 similar to that shown in FIG. 8, may subsequently be formed on the conductive material 160 on the bottom contact pads 150, where the external interconnects 180 can be attached to the conductive material 160 without any active treatment to the conductive material 160.

FIG. 9 is a flow diagram 200 of the methods of forming conductive materials on contact pads for a semiconductor package. In one embodiment, a method of forming conductive materials on contact pads include providing a substrate having an upper surface and a lower surface, where the lower surface is opposite the upper surface as indicated in step 202. Next, contact pads can be formed over the upper surface of the substrate in step 204. A conductive material can be formed over the contact pad in step 206, where the steps of forming the conductive material includes initially depositing the conductive material (216). The types of conductive material that can be deposited include silver (Ag), platinum (Pt), gold (Au), copper (Cu), carbon nanotube (CNT), graphene, organic metal, or mixtures thereof, among others. Optionally, dispersing or allowing the conductive material to disperse from an initial area to a final area, where the final area greater than the initial area (218). In one embodiment, to enhance the dispersion step, the contact pads may be treated with hydrophilic plasma 222 prior to the formation steps 216, 218. Last but not least, heating the conductive material to cure and solidify the conductive material (220).

In one embodiment, the depositing step 216 can be done such that the conductive material is at a first material state. The first material state includes liquid, viscous or paste form, among others. The first material state may also include an initial or first profile. Subsequently, the heating step 220 can be performed to alter or transform the conductive material from the first material state to a second material state, where the second material state is different from the first material state. The second material state includes solid, crystal or sintered form, among others. The second material state may also include a final or second profile, the final or second profile being different from the initial or first profile. This may be as a result of the heating step 220 which may cause shrinkage of the conductive ink, droplet, liquid or paste. Regardless, the conductive material can be formed without a lithographic process involving the coating and removal of a photoresist material. Furthermore, the conductive material can be formed without the use of a traditional metallization process in which the material is deposited and formed as is.

After formation of the conductive material, an interconnect structure can be mounted over the conductive material, where the interconnect structure is attached to the conductive material without any active treatment to the conductive material after the formation of the conductive material as indicated in step 208. In one embodiment, formation of the conductive material over the contact pad can prevent oxidation of the contact pad.

In one embodiment, the method further includes mounting a semiconductor package over the interconnect structure, where the semiconductor package includes an integrated circuit device as shown in step 210. In another embodiment, the method further includes forming a plurality of external interconnects on the lower surface of the substrate, where the external interconnects are in communication with the integrated circuit device as indicated in step 212.

In one embodiment, a method of forming conductive materials on contact pads include providing a substrate having an upper surface and a lower surface, where the lower surface opposite the upper surface as shown in step 202. Next, first and second sets of contact pads are formed over the upper surface of the substrate, where first set of contact pads are central of the substrate while the second set of contact pads are peripheral of the substrate as indicated in step 204. An integrated circuit device can be mounted over the first set of contact pads in step 214 followed by formation of external interconnects on the lower surface of the substrate, the external interconnects in communication with the integrated circuit device as indicated in step 224. In one embodiment, the integrated circuit device is a flip chip device. The formation of the external interconnects 224 can be substantially similar to that of step 212 and it will be understood and appreciated by those skilled that the formation of these parts 210, 212, 214, 224 can occur interchangeably anywhere throughout this process flow diagram 200.

Conductive material can be formed over the second set of contact pad in step 206, the formation steps include: depositing the conductive material (216), optionally dispersing or allowing the conductive material to disperse from an initial area to a final area, where the final area is greater than the initial area (218), and heating of the conductive material (220).

In another embodiment, the second conductive material can be deposited over the second set of contact pad such that the second conductive material is deposited as at a third material state during the depositing step 216. The third material state may be similar to that of the first state to include liquid, viscous or paste form, among others. The third material state may also include a third profile, which can be substantially similar to that of the first or initial profile. Next, the second conductive material can be heated at the heating step 220 bypassing the dispersing step 218 to transform the second conductive material from the third material state to a fourth material state, where the fourth material state is different from the third material state. The fourth material state may be similar to that of the second material state to include solid, crystal or sintered form, among others. The fourth material state may also include a fourth profile, the fourth profile being different from the third profile but may be substantially similar to that of the final or second profile. Like with the first conductive material, the second conductive material can be formed without a lithographic process involving the coating and removal of a photoresist material. Furthermore, the second conductive material can be formed without the use of a traditional metallization process in which the material is deposited and formed as is.

Once the second conductive material has been formed, an interconnect structure can be mounted over the second conductive material, where the interconnect structure is attached to the second conductive material without any active treatment to the second conductive material after the forming process as indicated in step 208.

In one embodiment, the method further includes mounting a semiconductor package over the interconnect structure, where the semiconductor package is in communication with the integrated circuit device in step 210. In another embodiment, the method further includes forming a plurality of external interconnects on the lower surface of the substrate, where the external interconnects are in communication with at least one of the semiconductor package and the integrated circuit device in step 212.

In one embodiment, a method of forming conductive materials on contact pads include providing a substrate having an upper surface and a lower surface, where the lower surface is opposite the upper surface in step 202. Next, first, second and third sets of contact pads can be formed on the substrate, where the first set of contact pads is formed on the lower surface while the second and third sets of contact pads are formed on the upper surface, the third set of contact pads being adjacent the second set of contact pads (204). In one embodiment, the second set of contact pads can be formed about a peripheral region of the upper surface of the substrate while the third set of contact pads can be formed about a central region of the upper surface of the substrate.

Next, an integrated circuit device can be mounted over the third set of contact pads as shown in step 214 followed by formation of external interconnects on the lower surface of the substrate, e.g., the first conductive material over the first set of contact pads on the lower surface of the substrate. The plurality of external interconnects can be coupled to the first conductive material without any active treatment to the first conductive material after the forming steps discussed above. The external interconnects can be in communication with the integrated circuit device as indicated in step 212. In one embodiment, the integrated circuit device is a flip chip device.

In one embodiment, a first conductive material can be formed over the first set of contact pads in step 206 including the depositing step 216, the optional dispersing step 218, and the heating step 220. Similarly, a second conductive material can be formed over the second set of contact pads in step 206 including the similar depositing step 216, the optional dispersing step 218, and the heating step 220. Likewise, a third conductive material can be formed over the third set of contact pads in step 206 including the similar depositing step 216, the optional dispersing step 218, and the heating step 220. In one embodiment, the second conductive material and the third conductive material can be concurrently carried out. In other words, both conductive materials can be formed on their respective contact pads at the same time. Formation of the third conductive material may be substantially similar to those of the first conductive material and the second conductive material and will not be elaborated further herein. The third conductive material may include a fifth state transformed to a sixth state, as well as a fifth profile transformed to a sixth profile after the heating step 220 similar to that discussed above.

In one embodiment, an interconnect structure can be mounted over the second conductive material as indicated in step 208, where the interconnect structure is attached to the second conductive material without any active treatment to the second conductive material after the forming step described above. In another embodiment, a semiconductor package can be mounted over the interconnect structure, where the semiconductor package is in communication with the integrated circuit device in step 210. In yet another embodiment, the plurality of external interconnects can be formed over the first conductive material, where the plurality of external interconnects can be in communication with at least one of the semiconductor package and the integrated circuit device as indicated in step 212.

In some embodiments, the first, second and third conductive materials can be deposited including one of the following material compositions: silver (Ag), platinum (Pt), gold (Au), copper (Cu), carbon nanotube (CNT), graphene, organic metal, or mixtures thereof. The formation of the conductive materials can prevent oxidation of the respective contact pads. For example, the first conductive material over the first set of contact pads can prevent oxidation of the first set of contact pads, the second conductive material over the second set of contact pads can prevent oxidation of the second set of contact pads, and the third conductive material over the third set of contact pads can prevent oxidation of the third set of contact pads. Each of the contact pads can be treated with hydrophilic plasma prior to the formation or deposition of the conductive material.

Although the current description has been described in detail with reference to several embodiments, additional variations and modifications exist within the scope and spirit of the disclosure.

What is claimed is:

1. A method comprising:
(a) providing a substrate having an upper surface and a lower surface, the lower surface opposite the upper surface;
(b) forming a contact pad over the upper surface of the substrate;
(c) forming a conductive material over the contact pad including:
(i) depositing the conductive material;
(ii) dispersing the conductive material from an initial area to a final area, the final area greater than the initial area;
(iii) heating the conductive material; and
(d) mounting an interconnect structure over the conductive material, wherein the interconnect structure is attached to the conductive material without any active treatment to the conductive material after the forming step (c).

2. The method of claim 1, further comprising:
(e) mounting a semiconductor package over the interconnect structure, the semiconductor package having an integrated circuit device.

3. The method of claim 2, further comprising:
(f) forming a plurality of external interconnects on the lower surface of the substrate, the external interconnects in communication with the integrated circuit device.

4. The method of claim 1, wherein the depositing step (i) of the forming step (c) includes depositing the conductive material including at least one of silver (Ag), platinum (Pt), gold (Au), copper (Cu), carbon nanotube (CNT), graphene, organic metal, and mixtures thereof.

5. The method of claim 1, wherein the forming step (c) includes forming the conductive material over the contact pad to prevent oxidation of the contact pad.

6. The method of claim 1, further comprising:
treating the contact pads with hydrophilic plasma prior to the forming step (c).

7. A method comprising:
(a) providing a substrate having an upper surface and a lower surface, the lower surface opposite the upper surface;
(b) forming first and second sets of contact pads over the upper surface of the substrate, the first set of contact pads disposed about a central region of the substrate and the second set of contact pads disposed about a peripheral region of the substrate;
(c) mounting an integrated circuit device over the first set of contact pads;
(d) forming a conductive material over the second set of contact pads including:
(i) depositing the conductive material;
(ii) dispersing the conductive material from an initial area to a final area, the final area greater than the initial area;
(iii) heating the conductive material; and
(e) mounting an interconnect structure over the conductive material, wherein the interconnect structure is attached to the conductive material without any active treatment to the conductive material after the forming step (d).

8. The method of claim 7, further comprising:
(f) mounting a semiconductor package over the interconnect structure, the semiconductor package in communication with the integrated circuit device.

9. The method of claim 8, further comprising:
(g) forming a plurality of external interconnects on the lower surface of the substrate, the external interconnects in communication with at least one of the semiconductor package and the integrated circuit device.

10. The method of claim 7, wherein the mounting step (c) includes mounting the integrated circuit device over the first set of contact pads, wherein the integrated circuit device is a flip chip device.

11. The method of claim 7, wherein the depositing step (i) of the forming step (d) includes depositing the conductive material including at least one of silver (Ag), platinum (Pt), gold (Au), copper (Cu), carbon nanotube (CNT), graphene, organic metal, and mixtures thereof.

12. The method of claim 7, wherein the forming step (d) includes forming the conductive layer over the second set of contact pads to prevent oxidation of the second set of contact pads.

13. The method of claim 7, further comprising:
treating the second set of contact pads with hydrophilic plasma prior to the forming step (d).

14. A method comprising:
(a) providing a substrate having an upper surface and a lower surface, the lower surface opposite the upper surface;
(b) forming first, second and third sets of contact pads on the substrate, wherein:
the first set of contact pads is formed on the lower surface,
the second set of contact pads is formed on the upper surface, and
the third set of contact pads is formed on the upper surface, the third set of contact pads adjacent the second set of contact pads;
(c) mounting an integrated circuit device over the third set of contact pads;
(d) forming a first conductive material over the first set of contact pads including:
(i) depositing the first conductive material;
(ii) dispersing the first conductive material from first initial area to first final area, the first final area greater than the first initial area;
(iii) heating the first conductive material;
(e) forming a second conductive material over the second set of contact pads including:
(i) depositing the second conductive material;
(ii) dispersing the second conductive material from second initial area to second final area, the second final area greater than the second initial area;
(iii) heating the second conductive material;
(f) forming a plurality of external interconnects over the first conductive material, wherein the external interconnects are coupled to the first conductive material without any active treatment to the first conductive material after the forming step (d); and
(g) mounting an interconnect structure over the second conductive material, wherein the interconnect structure is attached to the second conductive material without any active treatment to the second conductive material after the forming step (e).

15. The method of claim 14, wherein the forming step (b) includes forming the second set of contact pads about a peripheral region of the upper surface of the substrate and forming the third set of contact pads about a central region of the upper surface of the substrate.

16. The method of claim 14, further comprising:
forming a third conductive material over the third set of contact pads prior to the mounting step (c), the forming step including:
(i) depositing the third conductive material;
(ii) dispersing the third conductive material from third initial area to third final area, the third final area greater than the third initial area; and
(iii) heating the third conductive material.

17. The method of claim 16, wherein the forming the third conductive material prior to the mounting step (c) and the forming step (e) can be carried out concurrently.

18. The method of claim 14, wherein the mounting step (c) includes mounting the integrated circuit device over the third set of contact pads, wherein the integrated circuit device is a flip chip device.

19. The method of claim 14, further comprising:
(h) mounting a semiconductor package over the interconnect structure, the semiconductor package in communication with the integrated circuit device.

20. The method of claim 19, wherein the forming step (f) includes forming the plurality of external interconnects over the first conductive material, the plurality of external interconnects in communication with at least one of the semiconductor package and the integrated circuit device.
